(19) United States
(12) Patent Application Publication
(10) Pub. No.: US 2026/0299398 A1
(43) Pub. Date: Oct. 1, 2026

(54) REFLECTIVE PHOTOMASK AND METHOD FOR MANUFACTURING REFLECTIVE PHOTOMASK

(71) Applicant: RAPIDUS CORPORATION, Tokyo (JP)

(72) Inventor: Eisuke Narita, Albany, NY (US)

(21) Appl. No.: 19/454,455

(22) Filed: Jan. 21, 2026

Related U.S. Application Data
(60) Provisional application No. 63/779,756, filed on Mar. 28, 2025.

(30) Foreign Application Priority Data
Oct. 20, 2025 (JP) 2025-176796

(51) Int. Cl. G03F 1/24; G03F 1/48; G03F 1/52; G03F 1/54; G03F 1/70

(52) U.S. Cl. CPC G03F 1/24; G03F 1/48; G03F 1/52; G03F 1/54; G03F 1/70

(57) ABSTRACT

A reflective photomask according to an embodiment includes: a reflector that is provided on a substrate, and reflects exposure light; and an absorption film that is provided in a predetermined pattern on the reflector, and absorbs the exposure light. The reflective photomask includes a first portion that is doubly exposed when the pattern is transferred using the exposure light, and a second portion other than the first portion. The reflector includes a first exposed portion exposed in an opening of the pattern in the first portion, and a second exposed portion exposed in an opening of the pattern in the second portion. A first reflectance that is the reflectance of the exposure light by the first exposed portion is lower than a second reflectance that is the reflectance of the exposure light by the second exposed portion.

### BACKGROUND OF THE INVENTION

### 1. TECHNICAL FIELD

The disclosure of the present specification and the drawings relates to a reflective photomask and a method for manufacturing the reflective photomask.

### 2. DESCRIPTION OF THE RELATED ART

In the technology of High-NA exposure considered to be introduced in the future, there is a possibility that double exposure due to stitching will become a problem. That is, in a case where a double exposure portion to be doubly exposed is provided in a reflective photomask, there is a possibility that dimension control on the portion corresponding to the double exposure portion will become difficult in a semiconductor device to be manufactured using the reflective photomask. For example, in a case where the accuracy of overlapping exposure light beams drops in the double exposure portion of the reflective photomask, there is a possibility that a pattern different from the expected pattern will be formed in the portion corresponding to the double exposure portion in the semiconductor device, and the electrical characteristics of the portion might be degraded.

### SUMMARY OF THE INVENTION

The disclosure of the present specification and the drawings has been made to solve the above problem, and aims to facilitate dimension control on the portion corresponding to a double exposure portion in a semiconductor device.

A reflective photomask according to an embodiment includes: a reflector that is provided on a substrate, and reflects exposure light; and an absorption film that is provided in a predetermined pattern on the reflector, and absorbs the exposure light. The reflective photomask includes a first portion that is doubly exposed when the pattern is transferred using the exposure light, and a second portion other than the first portion. The reflector includes a first exposed portion exposed in an opening of the pattern in the first portion, and a second exposed portion exposed in an opening of the pattern in the second portion. A first reflectance that is the reflectance of the exposure light by the first exposed portion is lower than a second reflectance that is the reflectance of the exposure light by the second exposed portion.

### BRIEF DESCRIPTION OF THE DRAWINGS

FIG. 1 is a plan view of a reflective photomask according to a first embodiment;

FIG. 2 is a cross-sectional view of the reflective photomask according to the first embodiment;

FIG. 3 is an enlarged view of a region R1 shown in FIG. 2;

FIG. 4 is an enlarged view of a region R2 shown in FIG. 2;

FIG. 5A is a cross-sectional view for explaining a process of manufacturing the reflective photomask according to the first embodiment;

FIG. 5B is a cross-sectional view for explaining the process of manufacturing the reflective photomask according to the first embodiment, continuing from FIG. 5A;

FIG. 5C is a cross-sectional view for explaining the process of manufacturing the reflective photomask according to the first embodiment, continuing from FIG. 5B;

FIG. 5D is a cross-sectional view for explaining the process of manufacturing the reflective photomask according to the first embodiment, continuing from FIG. 5C;

FIG. 5E is a cross-sectional view for explaining the process of manufacturing the reflective photomask according to the first embodiment, continuing from FIG. 5D;

FIG. 5F is an enlarged view of the region R1 shown in FIG. 5E;

FIG. 6 is a cross-sectional view of a reflective photomask according to a second embodiment;

FIG. 7 is a cross-sectional view of a reflective photomask according to a third embodiment;

FIG. 8 is a cross-sectional view for explaining a process of manufacturing the reflective photomask according to the third embodiment; and

FIG. 9 is a cross-sectional view of a reflective photomask according to a fourth embodiment.

### DETAILED DESCRIPTION

Embodiments of a reflective photomask and a method for manufacturing the reflective photomask will be described below with reference to the drawings. Note that the drawings are schematic or conceptual, and the ratio and the like of each portion are not necessarily the same as actual ones. Also, in the following description, components having substantially the same functions and configurations are denoted by the same reference numerals, and redundant description will be made only when necessary.

Further, for ease of explanation, in each cross-sectional view, the side of an absorption film 5 will be referred to as the “upper” side, and the side of a substrate 2 will be referred to as the “lower” side. However, this expression is merely for convenience sake, and is not related to the direction of gravitational force.

### First Embodiment

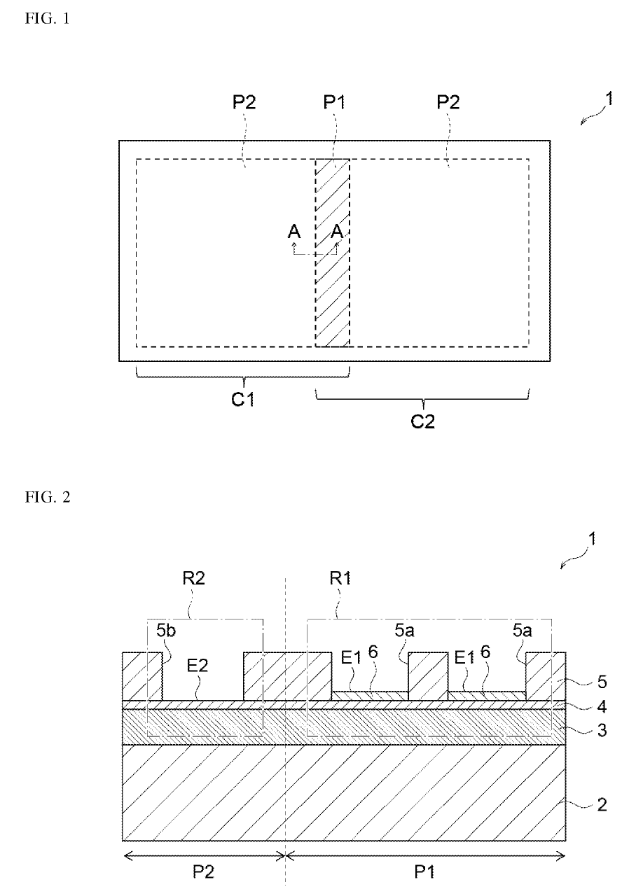

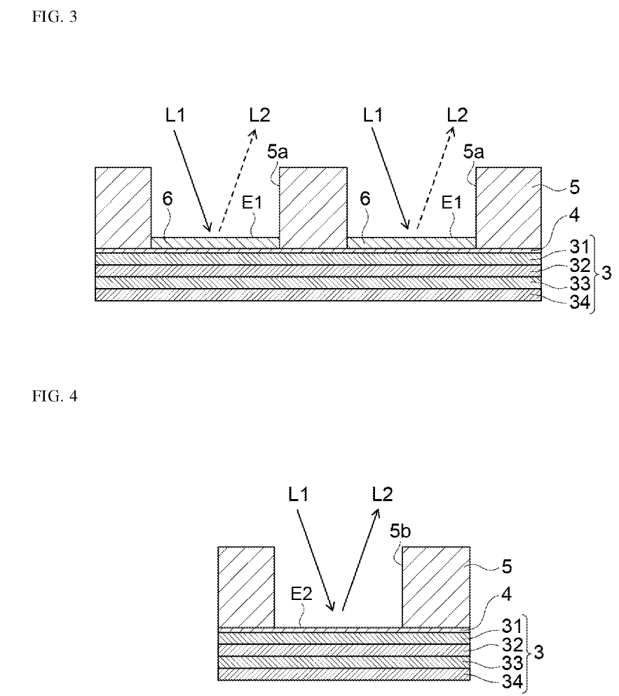

A reflective photomask 1 according to a first embodiment is described with reference to FIGS. 1 to 4. FIG. 1 is a plan view of the reflective photomask 1 according to the first embodiment. FIG. 2 is a cross-sectional view of the reflective photomask 1 according to the first embodiment, taken along the A-A line defined in FIG. 1. FIG. 3 is an enlarged view of a region R1 shown in FIG. 2. FIG. 4 is an enlarged view of a region R2 shown in FIG. 2.

The reflective photomask 1 is used to transfer a predetermined pattern onto a semiconductor substrate or the like by reflecting exposure light emitted thereon. In the present embodiment, the reflective photomask 1 is used for High-NA exposure. In this case, the exposure light is extreme ultraviolet light (EUV light), for example.

As illustrated in FIG. 1, the reflective photomask 1 is irradiated with exposure light, divided into an exposure region C1 and an exposure region C2, for example. At this point of time, a first portion P1 that is a double exposure portion, is formed in a connecting portion (stitching region) between the exposure region C1 and the exposure region C2, as indicated by hatching. That is, the first portion P1 is a portion that is doubly exposed when the predetermined pattern is transferred onto the semiconductor substrate, using exposure light. The first portion P1 is also an overlap portion between the exposure region C1 and the exposure region C2. A second portion P2 is a portion other than the first portion P1, for example. In the example in FIG. 1, the second portion P2 is both portions each belonging to one of the exposure region C1 and the exposure region C2. The second portion P2 may be referred to as a single exposure portion.

Note that the reflective photomask 1 may be irradiated with exposure light, divided into three or more exposure regions. In this case, the first portion P1, which is a double exposure portion, may be formed separately at a plurality of locations.

As illustrated in FIG. 2, the reflective photomask 1 according to the present embodiment includes a substrate 2, a multilayer reflective film 3, a protective film 4, an absorption film 5, and a thin film 6. The material of the substrate 2 is silicon or synthetic quartz, for example.

The multilayer reflective film 3 is provided on the substrate 2, and reflects exposure light. The multilayer reflective film 3 includes a plurality of layers having different refractive indexes with respect to exposure light. In a case where EUV light is used as exposure light, the layers in the multilayer reflective film 3 are layers formed with Mo and layers formed with Si, which are alternately stacked. In the examples in FIGS. 3 and 4, a first layer 31, a second layer 32, a third layer 33, and a fourth layer 34 among the layers of the multilayer reflective film 3 are shown. Here, the first layer 31 is the layer located at the upper end of the multilayer reflective film 3. The second layer 32 is the layer directly below the first layer 31, the third layer 33 is the layer directly below the second layer 32, and the fourth layer 34 is the layer directly below the third layer 33. For example, the first layer 31 and the third layer 33 are layers formed with Mo, and the second layer 32 and the fourth layer 34 are layers formed with Si.

The protective film 4 is provided on the multilayer reflective film 3, and protects the multilayer reflective film 3. Specifically, the protective film 4 prevents oxidation of the layers formed with Mo in the multilayer reflective film 3. Alternatively, the protective film 4 protects the multilayer reflective film 3 when the reflective photomask 1 is cleaned or when the pattern of the absorption film 5 is formed. The material of the protective film 4 is Ru, for example. The protective film 4 is also called a capping layer.

The absorption film 5 is provided in a predetermined pattern on the protective film 4, and absorbs the exposure light emitted onto the reflective photomask 1. A predetermined exposure pattern is formed with the portion on which the absorption film 5 is provided and the portion on which the absorption film 5 is not provided. The material of the absorption film 5 is Ta, for example.

In the present embodiment, as illustrated in FIG. 2, openings 5a are provided in the absorption film 5 in the first portion P1, and an opening 5b is provided in the absorption film 5 in the second portion P2. The upper surface of the thin film 6 is exposed through the bottoms of the openings 5a, and the upper surface of the protective film 4 is exposed through the bottom of the opening 5b.

The thin film 6 is provided on the protective film 4 at the bottoms of the openings 5a. The material of the thin film 6 is the same as the material of the protective film 4, and contains Ru, for example. Note that the material of the thin film 6 may be different from the material of the protective film 4, as long as the material does not excessively absorb exposure light.

The multilayer reflective film 3, the protective film 4, and the thin film 6 constitute a reflector according to the present embodiment. In other words, the reflector according to the present embodiment includes the multilayer reflective film 3, the protective film 4, and the thin film 6. The reflector is provided on the substrate 2, and reflects exposure light.

Also, the reflector includes first exposed portions E1 exposed to the insides of the openings 5a in the first portion P1, and a second exposed portion E2 exposed to the inside of the opening 5b in the second portion P2. In the present embodiment, the upper surface of the thin film 6 is exposed in the first exposed portions E1, and the upper surface of the protective film 4 is exposed in the second exposed portion E2.

In the present embodiment, as the thin film 6 is provided, the thickness of the film provided on the multilayer reflective film 3 in the first exposed portions E1 is greater than the thickness of the film provided on the multilayer reflective film 3 in the second exposed portion E2. Specifically, in the first exposed portions E1, the protective film 4 and the thin film 6 are provided on the multilayer reflective film 3. In the second exposed portion E2, on the other hand, the protective film 4 is provided on the multilayer reflective film 3, but the thin film 6 is not provided. Because of this, a first reflectance that is the reflectance of the exposure light by the first exposed portions E1 is lower than a second reflectance that is the reflectance of the exposure light by the second exposed portion E2.

In the present embodiment, the first reflectance is a value that is 40% or greater and 60% or smaller of the second reflectance. Note that a reflectance is calculated as a ratio between the intensity of incident light L1 and the intensity of reflected light L2 illustrated in FIGS. 3 and 4, for example.

Note that the protective film 4 is not necessarily provided. In this case, the upper surface of the multilayer reflective film 3, or more specifically, the upper surface of the first layer 31 in the multilayer reflective film 3 is exposed in the second exposed portion E2.

As described above, in the reflective photomask 1 according to the first embodiment, the first reflectance that is the reflectance of the exposure light by the first exposed portions E1 located in the double exposure portion is lower than the second reflectance that is the reflectance of the exposure light by the second exposed portion E2 located in the single exposure portion. Accordingly, in a semiconductor device to be manufactured using the reflective photomask 1, the exposure amount (dose) in the portion corresponding to the double exposure portion can be made close to the exposure amount in the portion corresponding to the single exposure portion. Thus, in the semiconductor device, the dimension control in the portion corresponding to the double exposure portion can be facilitated. For example, it is possible to prevent thickening of the wiring in the portion due to an increase in the exposure amount in the portion corresponding to the double exposure portion. As a result, it is possible to reduce degradation of the electrical characteristics in the portion corresponding to the double exposure portion, and it is possible to improve the electrical characteristics of the semiconductor device.

Also, with the reflective photomask 1 according to the present embodiment, it is possible to avoid the necessity of using a large-sized reflective photomask or the like for avoiding double exposure. Accordingly, a semiconductor device can be manufactured more inexpensively. Furthermore, restraints on design and the like for avoiding double exposure can be reduced.

### Method for Manufacturing Reflective Photomask According to First Embodiment

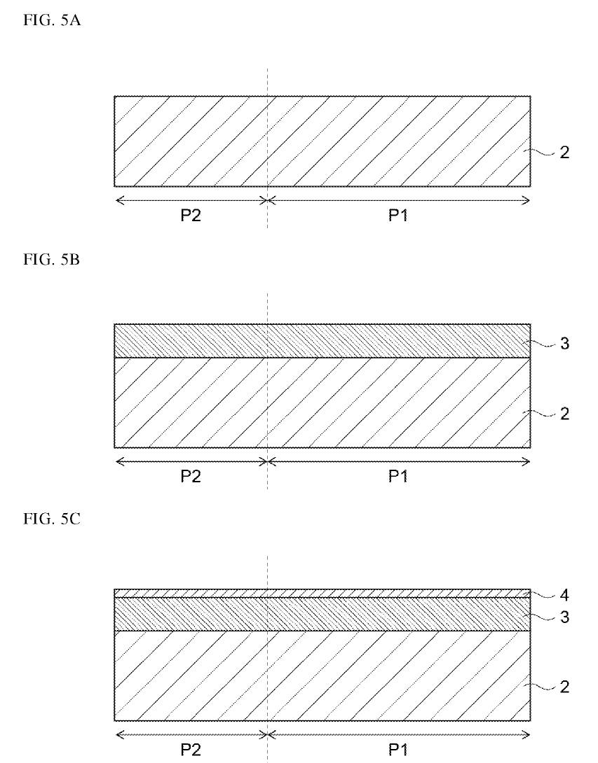

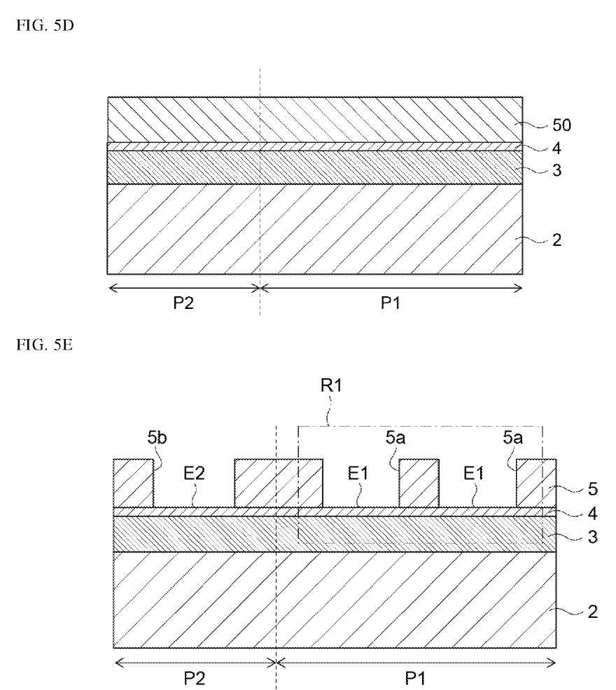

Next, an example of a method for manufacturing the reflective photomask 1 according to the present embodiment is described with reference to FIGS. 5A to 5F. FIGS. 5A to 5E are cross-sectional views for explaining the process of manufacturing the reflective photomask 1 according to the first embodiment. FIG. 5F is an enlarged view of the region R1 shown in FIG. 5E.

First, as illustrated in FIG. 5A, the substrate 2 is prepared. As the substrate 2, synthetic quartz having a size of 6 inches square and a thickness of 0.25 inches is used, for example.

Next, as illustrated in FIG. 5B, a material containing Mo and a material containing Si is alternately stacked on the substrate 2 by sputtering or the like, so that the multilayer reflective film 3 is formed on the substrate 2. For example, the multilayer reflective film 3 is formed by stacking a total of 40 to 50 pairs of a Si film of about 4.2 nm in thickness and a Mo film of about 2.8 nm in thickness.

Next, as illustrated in FIG. 5C, a material containing Ru is deposited on the multilayer reflective film 3 by sputtering or the like, to form the protective film 4. The material containing Ru is deposited in a film thickness of about 2 to 4 nm, for example.

The step of forming the reflector on the substrate 2 in the present embodiment is realized by the step of forming the multilayer reflective film 3 and the step of forming the protective film 4 described above.

Next, as illustrated in FIG. 5D, a material containing Ta or a Ta compound is deposited on the protective film 4 by sputtering or the like, to form an absorption film 50. The material containing Ta or a Ta compound is deposited in a film thickness of about 30 to 100 nm, for example.

Next, as illustrated in FIGS. 5E and 5F, the absorption film 50 is partially removed by dry etching such as reactive ion etching (RIE), to form a pattern. Specifically, the openings 5a are formed in the absorption film 50 in the first portion P1, and the opening 5b is formed in the absorption film 50 in the second portion P2. As a result, the absorption film 5 remains.

Next, a step is performed so that the first reflectance that is the reflectance of the exposure light by the first exposed portions E1 becomes lower than the second reflectance that is the reflectance of the exposure light by the second exposed portion E2. In the present embodiment, as illustrated in FIG. 2, the thin film 6 is formed on the protective film 4 in the first exposed portions E1. More specifically, a material containing Ru is deposited on the protective film 4 exposed in the openings 5a by sputtering or the like, so the thin film 6 is formed on the protective film 4 in the first exposed portions E1.

Through the above process, the reflective photomask 1 according to the first embodiment is manufactured. By the method for manufacturing the reflective photomask 1 according to the present embodiment, the thin film 6 can be formed after a pattern is formed in the absorption film 50. Accordingly, it is possible to avoid changing the existing manufacturing process, and for example, it is possible to avoid the influence of the thin film 6 on the step of forming the pattern in the absorption film 50.

In the first embodiment described above, the thin film 6 is provided on the protective film 4 in the first exposed portions E1, so that the reflectance of the exposure light by the first exposed portions E1 is lowered. The present invention is not limited to this, and any method may be adopted to lower the reflectance of the exposure light by the first exposed portions E1. In the following, other methods for lowering the reflectance of the exposure light by the first exposed portions E1 are described as second to fourth embodiments.

### Second Embodiment

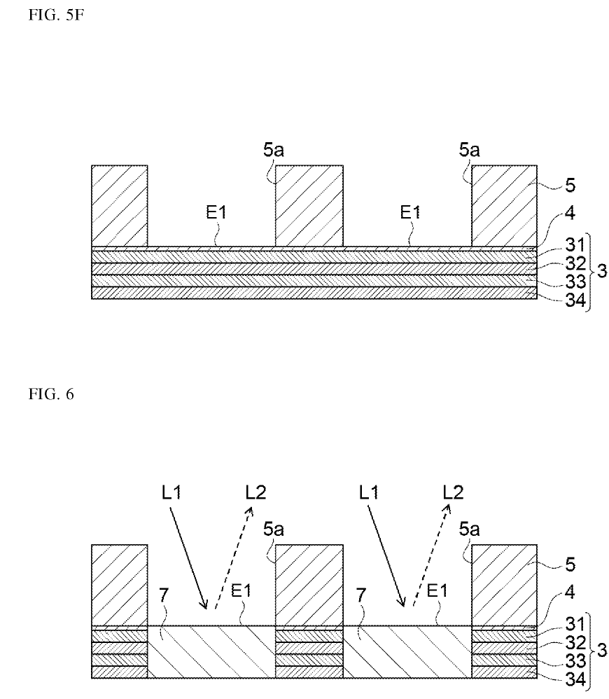

In the present embodiment, mixed regions in which materials of the reflector are mixed in the first exposed portions E1 are formed, so that the reflectance of the exposure light by the first exposed portions E1 is lowered. In the following, a reflective photomask 1 according to the present embodiment is described with reference to FIG. 6, attention being focused on the differences from the first embodiment. Note that, in the present embodiment, the thin film 6 is not provided.

FIG. 6 is a cross-sectional view of the reflective photomask 1 according to the second embodiment, and is a view corresponding to an enlarged view of the region R1 illustrated in FIG. 2.

As shown in FIG. 6, in the present embodiment, mixed regions 7 are provided in the first exposed portions E1. That is, of the reflector, the portions exposed through the bottoms of the openings 5a in the first portion P1 are the mixed regions 7. The upper surfaces of the mixed regions 7 are exposed in the first exposed portions E1. Note that, as illustrated in FIG. 4, the mixed regions 7 are not provided in the second exposed portion E2.

The mixed regions 7 are regions in which materials of the reflector are mixed. Specifically, the mixed regions 7 are regions in which the materials of the respective layers of the multilayer reflective film 3 and the material of the protective film 4 are mixed. That is, in the mixed regions 7, the multilayer reflective film 3 and the protective film 4 are in a state of not forming any layer. The mixed regions 7 contain Mo, Si, and Ru, for example. As such mixed regions 7 are provided, the first reflectance that is the reflectance of the exposure light by the first exposed portions E1 located in the double exposure portion is smaller than the second reflectance that is the reflectance of the exposure light by the second exposed portion E2 located in the single exposure portion.

Note that whether the mixed regions 7 are formed can be determined by analyzing a cross-section with a scanning electron microscope (SEM), for example.

As described above, with the reflective photomask 1 according to the second embodiment, in the semiconductor device being manufactured using the reflective photomask 1, the dimension control on the portion corresponding to the double exposure portion can be facilitated, as in the first embodiment.

### Method for Manufacturing Reflective Photomask According to Second Embodiment

The reflective photomask 1 according to the second embodiment is manufactured as follows, for example. First, in the process of manufacturing the reflective photomask 1 according to the first embodiment described above, the steps up to the step of forming a pattern in the absorption film 50 described with reference to FIGS. 5E and 5F are performed.

Next, a step is performed so that the first reflectance that is the reflectance of the exposure light by the first exposed portions E1 becomes lower than the second reflectance that is the reflectance of the exposure light by the second exposed portion E2. In the present embodiment, the materials of the reflector are mixed in the first exposed portions E1. Specifically, the insides of the openings 5a are irradiated with laser light or ions, so that the multilayer reflective film 3 and the protective film 4 at the bottoms of the openings 5a are heated. As illustrated in FIG. 6, the multilayer reflective film 3 and the protective film 4 are overheated at the bottoms of the openings 5a, so that the materials of the multilayer reflective film 3 and the protective film 4 are mixed to form the mixed regions 7 (mixing).

Through the above process, the reflective photomask 1 according to the second embodiment is manufactured. By the method for manufacturing the reflective photomask 1 according to the present embodiment, the mixed regions 7 can be formed after a pattern is formed in the absorption film 50. Accordingly, it is possible to avoid changing the existing manufacturing process, and for example, it is possible to avoid the influence of the mixed regions 7 on the step of forming the pattern in the absorption film 50.

### Third Embodiment

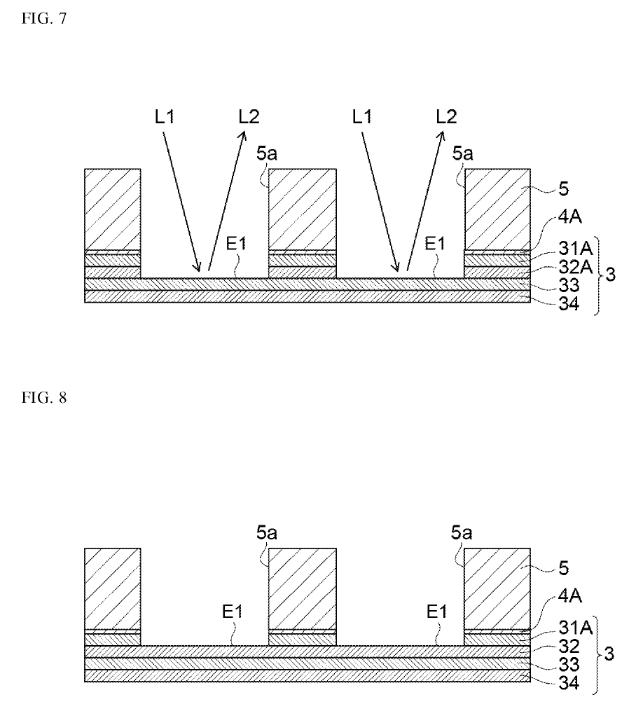

In the present embodiment, the number of stacked layers in the multilayer reflective film 3 is reduced in the first exposed portions E1, so that the reflectance of the exposure light by the first exposed portions E1 is lowered. In the following, a reflective photomask 1 according to the present embodiment is described with reference to FIGS. 7 and 8, attention being focused on the differences from the first embodiment. Note that, in the present embodiment, the thin film 6 is not provided.

FIG. 7 is a cross-sectional view of the reflective photomask 1 according to the third embodiment, and is a view corresponding to an enlarged view of the region R1 illustrated in FIG. 2. FIG. 8 is a cross-sectional view for explaining the process of manufacturing the reflective photomask 1 according to the third embodiment.

As illustrated in FIG. 7, in the present embodiment, the number of stacked layers in the multilayer reflective film 3 in the first exposed portions E1 is smaller than the number of stacked layers in the multilayer reflective film 3 in the second exposed portion E2. Because of this, the first reflectance that is the reflectance of the exposure light by the first exposed portions E1 located in the double exposure portion is smaller than the second reflectance that is the reflectance of the exposure light by the second exposed portion E2 located in the single exposure portion.

More specifically, in the example illustrated in FIG. 7, of a first layer 31A, a second layer 32A, a third layer 33, and a fourth layer 34 of the multilayer reflective film 3, the first layer 31A and the second layer 32A are not provided in the first exposed portions E1 and under the first exposed portions E1. That is, in the example illustrated in FIG. 7, the number of stacked layers in the multilayer reflective film 3 in the first exposed portions E1 is smaller than the number of stacked layers in the multilayer reflective film 3 in the second exposed portion E2 by two.

Note that, in the present embodiment, a protective film 4A is not provided in the first exposed portions E1, and the upper surface of the third layer 33 is exposed in the first exposed portions E1.

In the example illustrated in FIG. 7 and described above, the number of stacked layers in the multilayer reflective film 3 in the first exposed portions E1 is smaller than the number of stacked layers in the multilayer reflective film 3 in the second exposed portion E2 by two. The number of stacked layers in the multilayer reflective film 3 in the first exposed portions E1 is not limited to this, and may be smaller than the number of stacked layers in the multilayer reflective film 3 in the second exposed portion E2 by one, or three or more.

As described above, with the reflective photomask 1 according to the third embodiment, in the semiconductor device being manufactured using the reflective photomask 1, the dimension control on the portion corresponding to the double exposure portion can be facilitated, as in the first embodiment.

### Method for Manufacturing Reflective Photomask According to Third Embodiment

The reflective photomask 1 according to the third embodiment is manufactured as follows, for example. First, in the process of manufacturing the reflective photomask 1 according to the first embodiment described above, the steps up to the step of forming a pattern in the absorption film 50 described with reference to FIGS. 5E and 5F are performed.

Next, a step is performed so that the first reflectance that is the reflectance of the exposure light by the first exposed portions E1 becomes lower than the second reflectance that is the reflectance of the exposure light by the second exposed portion E2. In the present embodiment, the number of stacked layers in the multilayer reflective film 3 in the first exposed portions E1 is reduced. Specifically, first, as illustrated in FIG. 8, the protective film 4 and the first layer 31 of the multilayer reflective film 3 are removed at the bottoms of the openings 5a by dry etching or the like using F or Cl. Note that, when the protective film 4 and the first layer 31 are removed at the bottoms of the openings 5a, the protective film 4 and the first layer 31 may be simultaneously removed, or the first layer 31 may be removed after the protective film 4 is removed. As a result, the first layer 31A and the protective film 4A remain. After that, as illustrated in FIG. 7, the second layer 32 is removed at the bottoms of the openings 5a by dry etching or the like using F or Cl. As a result, the second layer 32A remains.

Through the above process, the reflective photomask 1 according to the third embodiment is manufactured. By the method for manufacturing the reflective photomask 1 according to the present embodiment, the mixed regions 7 can be formed after a pattern is formed in the absorption film 50. Accordingly, it is possible to avoid changing the existing manufacturing process, and for example, it is possible to avoid the influence of a decrease in the number of stacked layers in the multilayer reflective film 3 on the step of forming the pattern in the absorption film 50.

### Fourth Embodiment

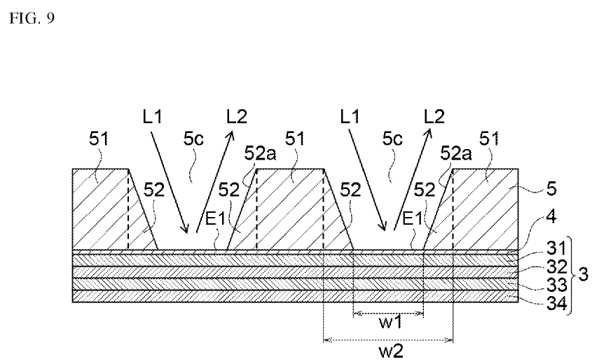

In the present embodiment, the shape of the sidewalls in the pattern is changed in the first portion P1, so that the reflectance of the exposure light by the first exposed portions E1 is lowered. In the following, a reflective photomask 1 according to the present embodiment is described with reference to FIG. 9, attention being focused on the differences from the first embodiment. Note that, in the present embodiment, the thin film 6 is not provided.

FIG. 9 is a cross-sectional view of the reflective photomask 1 according to the fourth embodiment, and is a view corresponding to an enlarged view of the region R1 illustrated in FIG. 2.

As illustrated in FIG. 9, the absorption film 5 of the reflective photomask 1 according to the present embodiment includes a plurality of main portions 51 and a plurality of additional portions 52. The plurality of main portions 51 has the same shape as the absorption film 5 in the first embodiment, for example. On the other hand, the additional portions 52 are provided so as to protrude into openings 5c in the first portion P1. In the example in FIG. 9, the width w1 of the bottom of each opening 5c, which is each first exposed portion E1, in a case where the additional portions 52 are provided is smaller than the width w2 in a case where the additional portions 52 are not provided. Because of this, the first reflectance that is the reflectance of the exposure light by the first exposed portions E1 located in the double exposure portion is smaller than the second reflectance that is the reflectance of the exposure light by the second exposed portion E2 located in the single exposure portion.

In the present embodiment, the additional portions 52 include sloped surfaces 52a that connect the upper surface of the absorption film 5 and the first exposed portions E1. That is, sloped surfaces 52a in which the sidewalls of the absorption film 5 are sloped are provided in the first portion P1, which is the double exposure portion.

Note that, in the present embodiment, the additional portions 52 include linearly sloped surfaces 52a. The additional portions 52 are not limited to this, and may include curved surfaces or the like that are added to the side portions of the main portions 51 and protrude toward the main portions 51 or toward the side opposite to the main portions 51.

As described above, with the reflective photomask 1 according to the fourth embodiment, in the semiconductor device being manufactured using the reflective photomask 1, the dimension control on the portion corresponding to the double exposure portion can be facilitated, as in the first embodiment.

### Method for Manufacturing Reflective Photomask According to Fourth Embodiment

The reflective photomask 1 according to the fourth embodiment is manufactured as follows, for example. First, in the process of manufacturing the reflective photomask 1 according to the first embodiment described above, the steps up to the step of forming the absorption film 50 described with reference to FIG. 5D are performed.

Next, a step is performed so that the absorption film 50 is partially removed to form a pattern, and that the first reflectance that is the reflectance of the exposure light by the first exposed portions E1 becomes lower than the second reflectance that is the reflectance of the exposure light by the second exposed portion E2. Specifically, as illustrated in FIG. 9, RIE is performed under conditions different from those in the first embodiment or with an etching gas of a different type from that in the first embodiment, for example, so that the openings 5c are formed in the first portion P1. Note that, in the second portion P2, RIE is performed under the same conditions as those in the first embodiment, to form the opening 5b. As a result, the absorption film 5 including the main portions 51 and the additional portions 52 is formed in the first portion P1.

Through the above process, the reflective photomask 1 according to the fourth embodiment is manufactured. By the method for manufacturing the reflective photomask 1 according to the present embodiment, at the same time as the step of forming the pattern in the absorption film 50, the first reflectance that is the reflectance of the exposure light by the first exposed portions E1 can be made lower than the second reflectance that is the reflectance of the exposure light by the second exposed portion E2.

Note that the embodiments described above merely disclose examples, and various modifications and combinations of the embodiments are possible. For example, the manufacturing methods in the manufacturing processes described in the embodiments described above are merely examples, and the reflective photomask manufacturing processes in the embodiments described above can be implemented by some other manufacturing method.

What is claimed is:

1. A reflective photomask that includes:
a reflector that is provided on a substrate, and reflects exposure light; and
an absorption film that is provided in a predetermined pattern on the reflector, and absorbs the exposure light,
the reflective photomask comprising:
a first portion that is doubly exposed when the pattern is transferred using the exposure light; and
a second portion other than the first portion,
wherein the reflector includes a first exposed portion exposed in an opening of the pattern in the first portion, and a second exposed portion exposed in an opening of the pattern in the second portion, and
a first reflectance that is a reflectance of the exposure light by the first exposed portion is lower than a second reflectance that is a reflectance of the exposure light by the second exposed portion.

2. The reflective photomask according to claim 1, wherein
the reflector includes:
a multilayer reflective film that is provided on the substrate, and includes a plurality of layers having different refractive indexes with respect to the exposure light;
a protective film that is provided on the multilayer reflective film, and protects the multilayer reflective film; and
a thin film provided on the protective film in the first exposed portion.

3. The reflective photomask according to claim 2, wherein a material of the thin film is the same as a material of the protective film.

4. The reflective photomask according to claim 3, wherein the material of the thin film is Ru.

5. The reflective photomask according to claim 1, wherein the reflector includes a mixed region in which materials of the reflector are mixed in the first exposed portion.

6. The reflective photomask according to claim 1, wherein
the reflector includes a multilayer reflective film that is provided on the substrate and includes a plurality of layers having different refractive indexes with respect to the exposure light, and
the number of stacked layers in the multilayer reflective film in the first exposed portion is smaller than the number of stacked layers in the multilayer reflective film in the second exposed portion.

7. The reflective photomask according to claim 1, wherein the absorption film includes a sloped surface connecting an upper surface of the absorption film and the first exposed portion in the first portion.

8. The reflective photomask according to claim 1, wherein the first reflectance is a value that is not smaller than 40% and not greater than 60% of the second reflectance.

9. The reflective photomask according to claim 1, wherein the exposure light is extreme ultraviolet light.

10. A method for manufacturing a reflective photomask that includes a first portion that is doubly exposed when a predetermined pattern is transferred using exposure light, and a second portion other than the first portion,
the method comprising:
a step of forming, on the substrate, a reflector that reflects the exposure light;
a step of forming, on the reflector, an absorption film that absorbs the exposure light;
a step of forming the pattern by partially removing the absorption film; and
a step of making a first reflectance lower than a second reflectance, the first reflectance being a reflectance of the exposure light by a first exposed portion exposed in an opening of the pattern in the first portion in the reflector, the second reflectance being a reflectance of the exposure light by a second exposed portion exposed in an opening of the pattern in the second portion in the reflector.

11. The method according to claim 10, wherein
the step of forming the reflector includes:
a step of forming, on the substrate, a multilayer reflective film including a plurality of layers having different refractive indexes with respect to the exposure light; and
a step of forming, on the multilayer reflective film, a protective film that protects the multilayer reflective film; and
the step of making the first reflectance lower than the second reflectance includes a step of forming a thin film on the protective film in the first exposed portion.

12. The method according to claim 10, wherein the step of making the first reflectance lower than the second reflectance includes a step of mixing materials of the reflector in the first exposed portion.

13. The method according to claim 10, wherein
the step of forming the reflector includes a step of forming, on the substrate, a multilayer reflective film including a plurality of layers having different refractive indexes with respect to the exposure light, and
the step of making the first reflectance lower than the second reflectance includes a step of reducing the number of stacked layers in the multilayer reflective film in the first exposed portion.

14. A method for manufacturing a reflective photomask that includes a first portion that is doubly exposed when a predetermined pattern is transferred using exposure light, and a second portion other than the first portion,
the method comprising:
a step of forming, on the substrate, a reflector that reflects the exposure light;
a step of forming, on the reflector, an absorption film that absorbs the exposure light; and
a step that is a step of forming the pattern by partially removing the absorption film, and is a step of making a first reflectance lower than a second reflectance, the first reflectance being a reflectance of the exposure light by a first exposed portion exposed in an opening of the pattern in the first portion in the reflector, the second reflectance being a reflectance of the exposure light by a second exposed portion exposed in an opening of the pattern in the second portion in the reflector.
